(19) United States
(12) Patent Application Publication
(10) Pub. No.: US 2025/0379158 A1
(43) Pub. Date: Dec. 11, 2025

(54) GUARD RING STRUCTURE

(71) Applicant: Taiwan Semiconductor Manufacturing Company, Ltd., Hsinchu (TW)

(72) Inventors: Chen-Chung Lai, Hsinchu County (TW); Chien-Ming Lai, Tainan City (TW); Wei-Ting Chen, Tainan City (TW); Yoyi Gong, Hsinchu County (TW)

(21) Appl. No.: 18/923,358

(22) Filed: Oct. 22, 2024

Related U.S. Application Data
(60) Provisional application No. 63/656,438, filed on Jun. 5, 2024.

(51) Int. Cl. H01L 23/00; H01L 21/768; H01L 23/48

(52) U.S. Cl. CPC H01L 23/562; H01L 21/76898; H01L 23/481

(57) ABSTRACT

A contact structure according to the present disclosure includes a device layer over a substrate, a dielectric structure over the device layer, a first etch stop layer (ESL) over the dielectric structure, a through via extending through the dielectric structure and the device layer and including a top portion of the through via rises above the first ESL, a guard ring structure over the first ESL and surrounding the top portion of the through via, a protective layer disposed over the guard ring structure, a second ESL disposed conformally over a top surface of the first ESL, sidewalls of the guard ring structure, sidewalls of the protective layer, and a top surface of the protective layer, and a dielectric layer of the second ESL.

### PRIORITY DATA

This application claims the benefit of U.S. Provisional Application No. 63/656,438, filed Jun. 5, 2024, which is hereby incorporated by reference in its entirety.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Through substrate vias (TSVs) are commonly used in 3DICs because they route electrical signal from one side of a silicon substrate of an IC to the other side thereof. The formation of TSVs may generate stress on surrounding structures, causing delamination and failures. Protective structures have been developed to reduce, absorb, or isolate the stress generated by TSVs.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart illustrating an embodiment of a method of forming a through substrate via through an integrated circuit (IC) device structure, according to various aspects of the present disclosure.

FIGS. 2-20 are fragmentary cross-sectional views of a work-in-progress (WIP) structure undergoing operations of the method in FIG. 1, according to various aspects of the present disclosure.

FIG. 21 is a fragmentary see-through top view of through vias and guard ring structures according to various aspects of the present disclosure.

### DETAILED DESCRIPTION

The present disclosure relates generally to integrated circuit devices, and more particularly, to interconnect structures for integrated circuit devices.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

An interconnect structure electrically couples various components (for example, transistors, resistors, capacitors, and/or inductors) fabricated on a substrate, such that the various components can operate as specified by design requirements. An interconnect structure includes a combination of dielectric layers and conductive layers configured to provide electrical signal routing. The conductive layers include via and contact features that provide vertical connections and conductive lines that provide horizontal connections. In some implementations, an interconnect structure may have five (5) to twenty (20) levels of metal layers (or metallization layers) that are vertically interconnected by via or contact features. During operation of the IC device, the interconnect structure routes signals among the components of the IC device and/or distribute signals (for example, clock signals, voltage signals, and/or ground signals) to the components. An interconnect structure is formed in a back-end-of-the-line (BEOL) process, typically formed after the front-end-of-the-line (FEOL) process forms the active devices such as a transistor on a substrate and the middle-end-of-the-line (MEOL) process forms source/drain contacts and gate contacts.

In some implementations, it is desirable to provide a vertical interconnect that extends through the interconnect structure and/or the substrate to facilitate various device structures, such as CMOS image sensors (CISs), a three-dimensional integrated circuit (3DIC), system of integrated chips (SoIC), system on chips (SoC), chiplets, neuromorphic computing circuit design, artificial intelligence (AI) systems, MEMS devices, radio frequency (RF) devices, wafer-on-wafer (WoW) devices, and so on. Such a vertical interconnect may be referred to as a through-silicon or through-substrate via (TSV) as it extends through, in whole or in part, the semiconductor substrate. The term TSV in the present disclosure broadly encompasses via structures that provide direct signal routing from a frontside of the substrate and a backside of the substrate or vice versa. A TSV is subject to mechanical stress caused by temperature variation during fabrication and operation of the structure including the TSV. The mechanical stress, if not absorbed or distributed, may impact the electrical characteristics of the TSV and the lifetime of the semiconductor device.

The present disclosure provides methods to form a guard ring structure that surrounds a portion of a TSV. The guard ring structure includes one or more films with different coefficients of thermal expansion and the one or more films can absorb and distribute the stress exerted on the TSV. By controlling a thickness and a composition of each film in the guard ring structure, the guard ring structure can be tailored to specific TSV designs and applications. The guard ring structures of the present disclosure have shown promising results in reducing the mechanical stress on TSVs and improving their electrical characteristics, which can lead to more efficient and durable semiconductor devices.

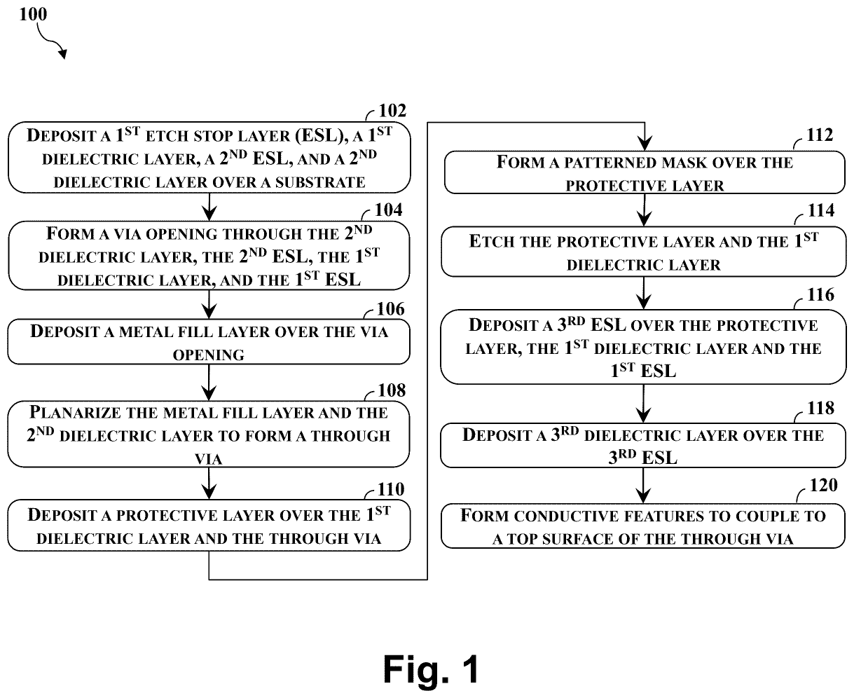

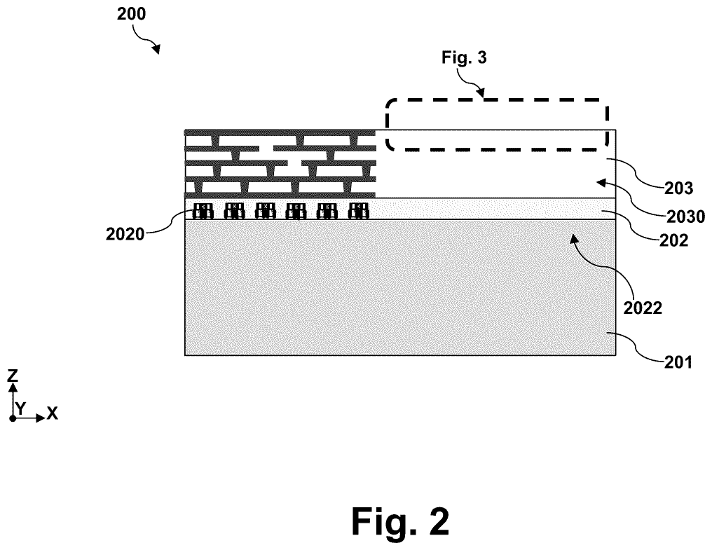

The various aspects of the present disclosure will now be described in more detail with reference to the figures. In that regard, FIG. 1 is a flowchart illustrating a method 100 of forming a device structure from a work-in-progress (WIP) structure 200 (shown in FIGS. 2-21) and a via structure through the device structure, according to various aspects of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-21, which are fragmentary cross-sectional views of the WIP structure 200 at different stages of fabrication according to various embodiments of method 100. Because the WIP structure 200 will be fabricated into a device structure, the WIP structure 200 may be referred to herein as a device structure 200 as the context requires. For avoidance of doubts, the X, Y and Z directions in FIGS. 2-21 are perpendicular to one another. Throughout the present disclosure, unless expressly otherwise described, like reference numerals denote like features.

The device structure 200 shown in the figures of the present disclosure is simplified and not all features in the device structure 200 are illustrated or described in detail. The device structure 200 shown in the figures may be a portion of an IC chip, a system on chip (SoC), or portion thereof, that may include various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof.

Referring to FIGS. 1 and 2-4, method 100 includes a block 102 where a first etch stop layer (ESL) layer 204, a first dielectric layer 206, a second ESL 208, and a second dielectric layer 210 are deposited over a substrate 201. Referring to FIG. 2, the substrate 201 is a part of a WIP structure 200, which further includes a device layer 202 over the substrate 201, a lower interconnect structure 203 over the device layer 202. In an embodiment, the substrate 201 includes silicon (Si). Alternatively or additionally, substrate 201 may include another elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide; an alloy semiconductor, such as silicon germanium (SiGe), GaAsP, AlInAs, AlGaAs, GaInAs, GaInP, and/or GalnAsP; or combinations thereof. Alternatively, substrate 201 may be a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. Substrate 201 can include various doped regions (not shown) depending on design requirements of device structure 200. In some implementations, substrate 201 may include p-type doped regions (for example, p-type wells) and n-type doped regions (for example, n-type wells). P-type doped regions may be doped with p-type dopants, such as boron (for example, BF₂), indium, other p-type dopant, or combinations thereof. N-type doped regions may be doped with n-type dopants, such as phosphorus (P), arsenic (As), other n-type dopant, or combinations thereof. In some implementations, substrate 201 includes doped regions formed with a combination of p-type dopants and n-type dopants. The various doped regions can be formed directly on and/or in substrate 201, for example, providing a p-well structure, an n-well structure, a dual-well structure, a raised structure, or combinations thereof. An ion implantation process, a diffusion process, and/or other suitable doping process can be performed to form the various doped regions.

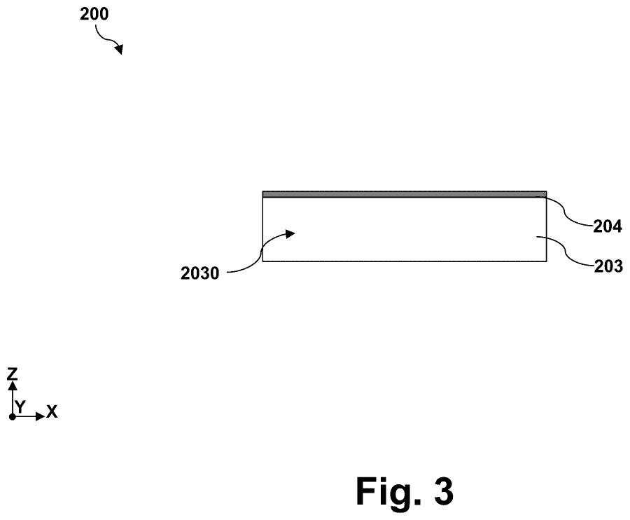

The device layer 202 includes transistors 2020 and middle-end-of-line (MEOL) contact structures. Each of the transistors 2020 may be a planar transistor or a multi-gate transistor, such as a fin-like FET (FinFET) or a gate-all-around (GAA) transistor. A FinFET includes a fin-shaped active region and gate structure wrapping over the fin-shaped active region. A GAA transistor has a channel region that is formed of multiple nanostructures in various shapes such nanowire, nanobar, or nanosheet. A GAA transistor includes a gate structure that wraps around each of the multiple nanostructures that extend between two epitaxial source/drain features. The multiple nanostructures may be formed from the substrate 201, which may be a silicon (Si) substrate, or from an epitaxial layer formed on the substrate 201. In the latter case, the epitaxial layer may include germanium (Ge) or silicon germanium (SiGe). While the transistors 2020 are shown as GAA transistors in FIG. 3 and subsequent figures, it should be understood that the transistors 2020 may as well be planar devices or FinFETs.

While not explicitly shown, the gate structure of the transistors 2020 includes an interfacial layer interfacing the nanostructures, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The gate dielectric layer may be formed by ALD, physical vapor deposition (PVD), CVD, oxidation, and/or other suitable methods.

The gate electrode layer of the gate structure may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

The epitaxial source/drain features of the transistors 2020 may be deposited using vapor-phase epitaxy (VPE), ultra-high vacuum CVD (UHV-CVD), molecular beam epitaxy (MBE), and/or other suitable processes. When the epitaxial source/drain features are n-type, they may include silicon (Si) doped with an n-type dopant, such as phosphorus (P) or arsenic (As). When the epitaxial source/drain features are p-type, it may include silicon germanium (SiGe) doped with a p-type dopant, such as boron (B) or boron difluoride (BF₂). In some alternative embodiments not explicitly shown in the figures, the epitaxial source/drain features may include multiple layers. In one example, an epitaxial source/drain feature may include a lightly doped first epitaxial layer interfacing the nanostructures, a heavily doped second epitaxial layer over the lightly doped first epitaxial layer, and a capping epitaxial layer disposed over the heavily doped second epitaxial layer. The first epitaxial layer has a lower dopant concentration or a smaller germanium content (when germanium is present) than the second epitaxial layer to reduce lattice mismatch defects. The second epitaxial layer has the highest dopant concentration or the highest germanium content (when germanium is present) to reduce resistance and increase strain on the channels. The capping epitaxial layer may have a smaller dopant concentration and germanium content (when germanium is present) than the second epitaxial layer to increase etch resistance.

The MEOL structures in the device layer 202 may include an interlayer dielectric (ILD) layer and a source/drain contact. The source/drain contact extends through the ILD layer to be physically and electrically coupled to the epitaxial source/drain feature. In some embodiments, the ILD layer may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), and/or other suitable dielectric materials. The ILD layer may be deposited using PECVD, FCVD, spin-on coating, or a suitable deposition technique. In some embodiments, after deposition of the ILD layer, it may be subject to an anneal process to improve its integrity. The source/drain contact may include ruthenium (Ru), cobalt (Co), nickel (Ni), or copper (Cu). In one embodiment, the source/drain contact includes cobalt (Co). The source/drain contact may be deposited using CVD, PVD, or a suitable method. Although not shown in figures, a contact etch stop layer (CESL) may be deposited before the ILD layer is deposited such that the CESL is disposed between the ILD layer and the epitaxial source/drain features. The CESL may include silicon nitride, silicon carbonitride or silicon oxynitride and may be deposited using CVD, ALD, or a suitable method. In some embodiments not explicitly shown, the source/drain contact may include a barrier layer to interface the ILD layer. Such a barrier layer may include a metal nitride, such as titanium nitride, tantalum nitride, tungsten nitride, cobalt nitride, or nickel nitride. Additionally, in order to reduce contact resistance, a silicide feature may be disposed between the source/drain contact and the epitaxial source/drain feature. The silicide feature may include titanium silicide.

As shown in FIG. 2, the device layer 202 includes a via formation region 2022 that is free of transistors 2020 and MEOL structures. That said, because the via formation region 2022 in the device layer 202 is formed along transistors 2020 and the MEOL structure, the via formation region 2032 includes an interlayer dielectric (ILD) layer and at least one etch stop layer (ESL). Because the via formation region 2030 is free of the transistors 2020 and the metal gate structures, formation of a via opening through the via formation region 2022 does not involve etching through metal features and is not going to produce undesirable metal debris.

The lower interconnect structure 203 may a lower portion of an interconnect structure that includes more levels of metallization layers. In some embodiments, The lower interconnect structure 203 may include the first three (3) to the first six (6) levels of metallization layers that are closest to the device layer 202. The number of levels in the lower interconnect structure 203 defines penetration of the result through via through the interconnect structure. After formation of the through via, additional levels of metallization layers are going to be formed over the lower interconnect structure 203. These additional levels of metallization layers may be collectively referred to as the upper interconnect structure. In some embodiments, the number of metallization layers in the lower interconnect structure 203 is selected such that the metallization layer immediately above the lower interconnect structure is a lot larger and thicker than the topmost metallization layer in the lower interconnect structure 203. This ensures that the through via lands on a metallization layer that is stronger mechanically.

Each of the metallization layers in the lower interconnect structure 203 includes an etch stop layer (ESL), an intermetal dielectric (IMD) layer disposed on the ESL, a plurality of vertically extending vias and horizontally metal lines disposed in the IMD layer and ESL. It can be said that ESLs interleave the IMD layers or that IMD layers interleave the ESLs. The ESLs may share the same composition and may include silicon nitride or silicon oxynitride. The IMD layers may share the same composition and may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. Example low-k dielectric materials include carbon doped silicon oxide, Xerogel, Aerogel, amorphous fluorinated carbon, benzocyclobutene (BCB), or polyimide. Vias and metal lines in the lower interconnect structure 203 may include titanium (Ti), ruthenium (Ru), nickel (Ni), cobalt (Co), copper (Cu), molybdenum (Mo), tungsten (W), aluminum (Al), and/or other suitable materials. In one embodiment, they may include copper (Cu). In some embodiments, in order to prevent electromigration from the metal material or oxygen diffusion from the dielectric features into the metal material, vias and metal lines may each include a barrier layer to interface the ESLs and IMD layers. The barrier layer may include titanium nitride (TiN), tantalum nitride (TaN), or cobalt nitride (CON). As shown in FIG. 2, the lower interconnect structure 203 includes a via formation region 2030 that is free of vias and metal lines. That said, because the via formation region 2030 is formed along with the vias and metal lines, the via formation region 2030 includes all the IMD layers and ESLs of the metallization layers. Because the via formation region 2030 is free of metal features, formation of a via opening through the via formation region 2030 does not involve etching through metal features and is not going to produce undesirable metal debris.

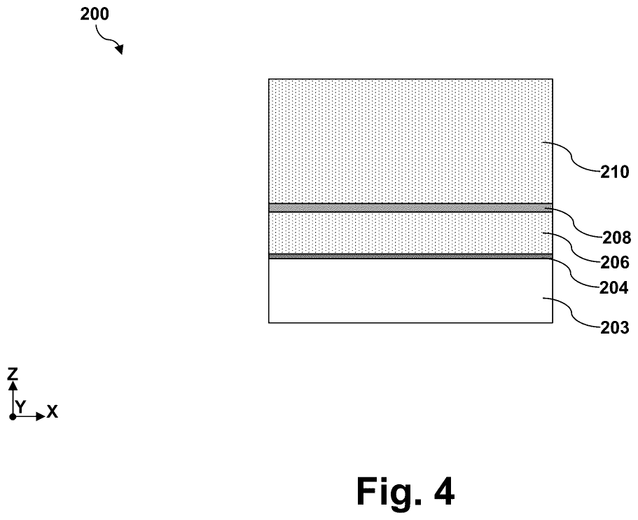

In order to illustrate the formation of the guard ring structure clearly, an area of the via formation region 2032 in FIG. 2 is enlarged and shown in FIG. 3 and subsequent figures such as FIGS. 4-17.

As illustrated in FIGS. 3 and 4, at block 102, the first ESL 204 is deposited on a top surface of the lower interconnect structure 203, including on the via formation region 2030. The first ESL 204 may include a dielectric material having silicon (Si), oxygen (O), hydrogen (H), nitrogen (N), carbon (C), aluminum (Al), or a combination thereof. In some embodiments, the first ESL 204 may include silicon carbonitride, aluminum oxide, or aluminum nitride. The first ESL 204 may be deposited using plasma-enhanced chemical vapor deposition (PECVD) or CVD. In some instances, the first ESL 204 may have a thickness between about 90 Å and about 150 Å. The first dielectric layer 206 is deposited over the first ESL 204. A composition of the first dielectric layer 206 is different from that of the first ESL 204. In some embodiments, the first dielectric layer 206 may include silicon oxide and may be deposited using CVD, spin-on coating, or flowable CVD (FCVD). In one embodiment, the first dielectric layer 206 is deposited using CVD to ensure its structural integrity. A thickness of the first dielectric layer 206 may vary widely depending on the design of the guard ring structure and a thickness of the metallization layer that accommodates the guard ring structure. In some instances, the thickness of the first dielectric layer 206 may be between about 10 Å and about 500 Å.

At block 102, the second ESL 208 is deposited over the first dielectric layer 206, as shown in FIG. 4. The second ESL 208 functions as a chemical mechanical polishing (CMP) stop layer. During a subsequent CMP planarization step, the second ESL 208 slows down the polishing to provide a CMP tool a signal to stop the CMP process. In some embodiments, the second ESL 208 may include a dielectric material having silicon (Si), oxygen (O), hydrogen (H), nitrogen (N), carbon (C), aluminum (Al), or a combination thereof. In some embodiments, the second ESL 208 may include silicon carbonitride, silicon nitride, silicon carbide, or silicon oxycarbonitride. The second ESL 208 may be deposited using PECVD or CVD. At block 102, a second dielectric layer 210 is deposited over the second ESL 208. The second dielectric layer 210 serves as a sacrificial layer to provide a depth of material to be polished away during the subsequent CMP planarization step. In order to provide an even planarization rate, the second dielectric layer 210 is formed using PECVD or CVD, instead of spin-on coating or FCVD. In some embodiments, the second dielectric layer 210 may include silicon oxide. The second dielectric layer 210 is thicker than the first dielectric layer 206. In some embodiments, the second dielectric layer 210 may have a thickness between 200 nm and 500 nm.

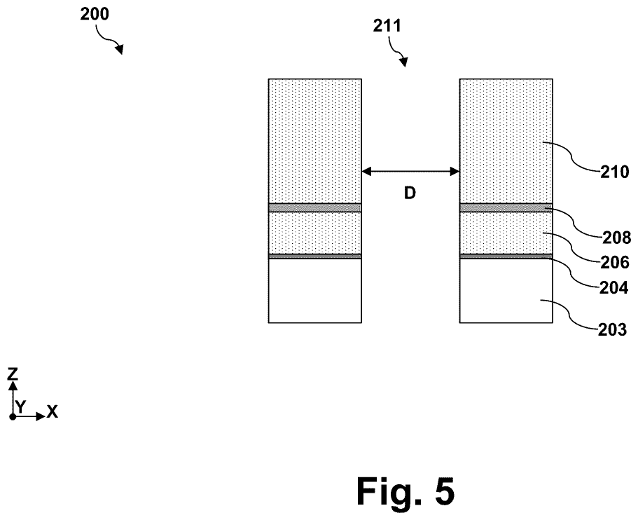

Referring to FIGS. 1 and 5, method 100 includes a block 104 where a via opening 211 is formed through the second dielectric layer 210, the second ESL 208, the first dielectric layer 206, and the first ESL 204. To form the via opening 211, a masking layer is formed over the second dielectric layer 210. The masking layer may include photoresist, silicon oxide, silicon nitride, silicon carbide, aluminum oxide, or titanium nitride. In one embodiment, the masking layer may be a photoresist layer having a thickness between about 5 μm and about 15 μm. The photoresist layer has a composition different from the ESLs, ILD layers and IMD layers that allows selectively etching the ESLs, ILD layers, the IMD layers, and the substrate 201. In this embodiment, the masking layer may be deposited using spin-on coating or FCVD. The deposited masking layer then undergoes a pre-exposure baking process, exposure to radiation reflected from or transmitted through a photomask, a post-exposure baking process, and developing process, so as to form a patterned masking layer. The patterned masking layer is then applied as an etch mask to etch the ESLs, ILD layers, IMD layers, and the substrate 201. The etch process here may be a dry etch process (e.g., a reactive ion etching (RIE) process). In some instances, an example dry etch process may implement an oxygen-containing gas (e.g., O₂), a fluorine-containing gas (e.g., SF₆ or NF₃), a chlorine-containing gas (e.g., Cl₂ and/or BCl₃), a bromine-containing gas (e.g., HBr), an iodine-containing gas, other suitable gases and/or plasmas, and/or combinations thereof. The etching at block 104 terminates when the via opening 211 reaches a depth between 2 μm and about 150 μm, such as between 10 μm and about 60 μm, into the substrate 201. In some embodiments, the via opening 211 is substantially circular in a top view (i.e., viewed along the Z direction) and has a diameter D between about 2 μm and about 12 μm. This diameter D defines the shape and dimension of the through via that is formed in the via opening 211.

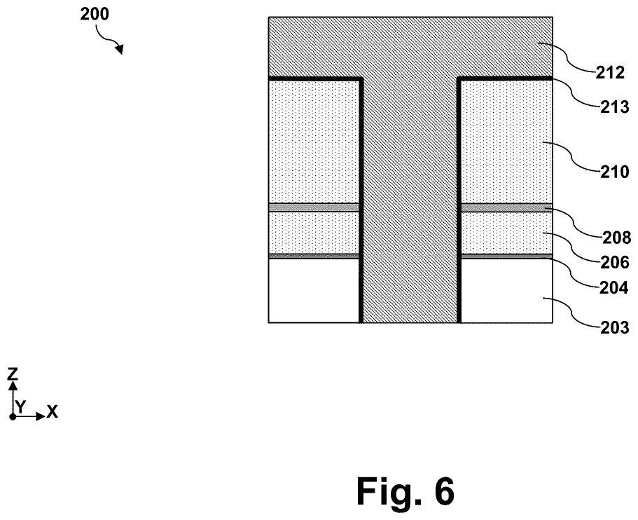

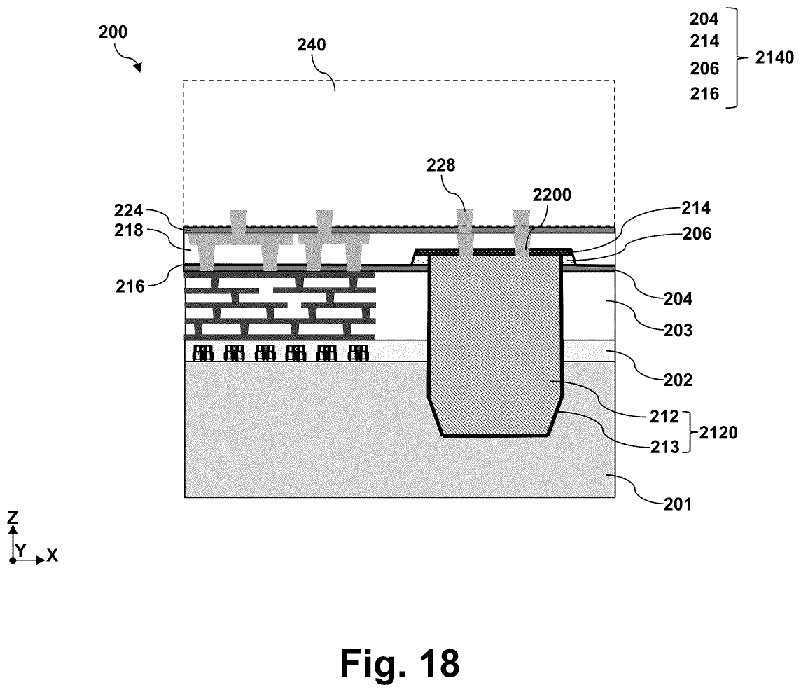

Referring to FIGS. 1 and 6, method 100 includes a block 106 where a metal fill layer 212 is formed over the via opening 211. At block 106, a barrier layer 213 and the metal fill layer 212 are deposited over the via opening 211. In some implementations, the barrier layer 213 may include tantalum nitride (TaN), titanium nitride (TiN), tungsten nitride (WN), or combinations thereof and the metal fill layer 212 may include copper (Cu), aluminum (Al), cobalt (Co), nickel (Ni), ruthenium (Ru), or a combination thereof. In one embodiment, the barrier layer 213 includes titanium nitride (TiN) and the metal fill layer 212 includes copper (Cu). At block 106, the barrier layer 213 is first deposited over the via opening 211 using PVD, CVD, MOCVD, ALD, or a combination thereof. Then the metal fill layer 212 is deposited using electroplating, PVD, CVD, electroless plating, or a suitable method. In one embodiment, the metal fill layer 212 is deposited using electroplating. In this embodiment, a seed layer may be deposited, using PVD or a suitable process, over the barrier layer 213. Then the metal fill layer 212 may be deposited over the seed layer using electroplating. In the embodiment where electroplating is used, the seed layer may include copper (Cu), titanium (Ti), or a combination thereof and the metal fill may include copper (Cu). As illustrated in FIG. 6, at block 106, the barrier layer 213 is deposited over the via opening 211 to be in direct contact with sidewalls of the substrate 201 (not shown in FIG. 6 but shown in FIGS. 18-21), sidewalls of the device layer 202 (not shown in FIG. 6 but shown in FIGS. 18-21), sidewalls of the via formation region 2030 of the lower interconnect structure 203, sidewalls of the first ESL 204, sidewalls of the first dielectric layer 206, sidewalls of the second ESL 208, and sidewalls of the second dielectric layer 210. The barrier layer 213 spaces the metal fill layer 212 apart from the substrate 201, the sidewalls of the device layer 202, the sidewalls of the via formation region 2030 of the lower interconnect structure 203, the sidewalls of the first ESL 204, sidewalls of the first dielectric layer 206, the sidewalls of the second ESL 208, and the sidewalls of the second dielectric layer 210.

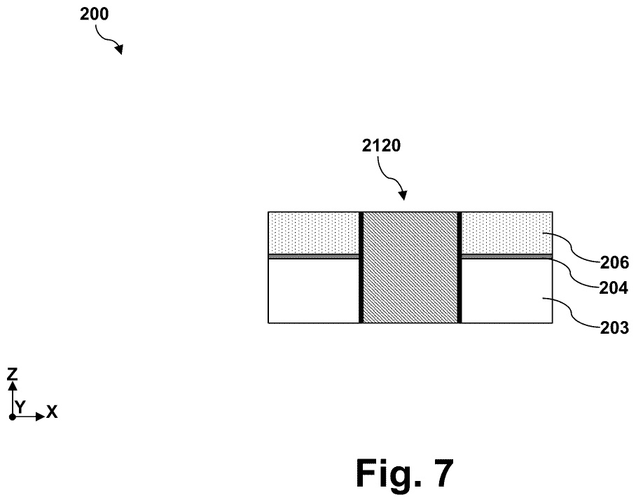

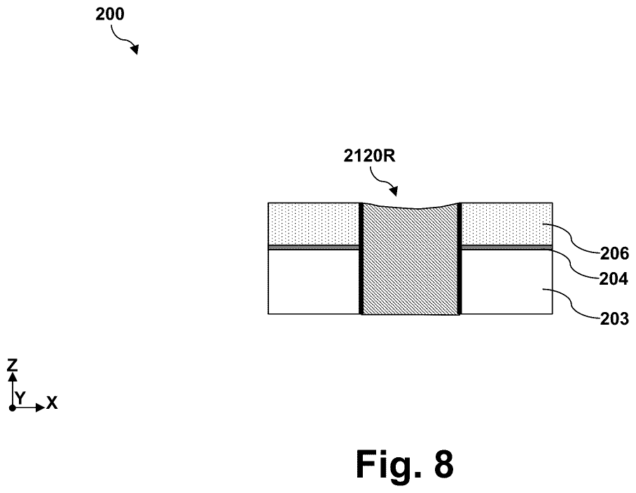

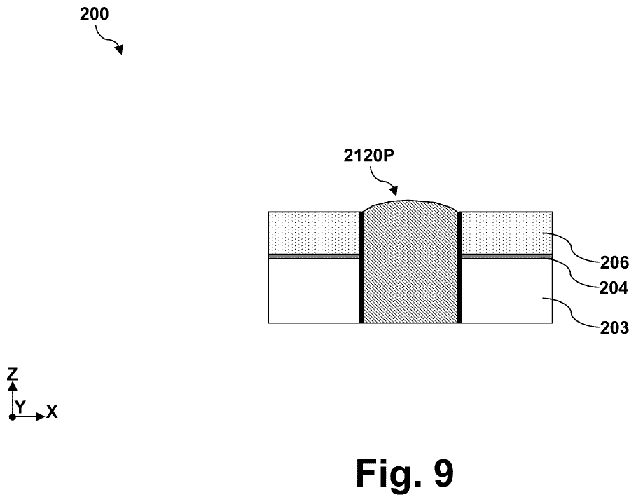

Referring to FIGS. 1 and 7-9, method 100 includes a block 108 where the metal fill layer 212 and the second dielectric layer 210 are planarized to form a through via 2120. After both the barrier layer 213 and the metal fill layer 212 are deposited over the second dielectric layer 210 and into the via opening 211, a planarization process, such as a CMP process, may be performed to remove excess metal fill layer 212, the second dielectric layer 210, and the second ESL 208. The additional thickness of the metal fill layer 212 helps ensures the surface flatness of the WIP structure 200. In some embodiments represented in FIG. 7, after the planarization at block 108, the through via 2120, which includes the barrier layer 213 and the metal fill layer 212, is formed. In some embodiments, the CMP process removes dielectric layers and the metal fill layer 212 at an even rate, top surfaces of the through via 2120 and the first dielectric layer 206 are substantially coplanar, as shown in FIG. 7. In some alternative embodiments, the metal fill layer 212 may be removed at a faster rate or a slower rate than the surrounding dielectric layer. Reference is first made to FIG. 8, which illustrates an alternative embodiment where the CMP process removes the metal fill layer 212 at a faster rate. As a result, FIG. 8 illustrates a recessed through via 2120R. As its name suggests, the recessed through via 2120R includes a top recess or a concave top surface that is lower than the first dielectric layer 206. As will be described below, the top recess may affect a cross-sectional profile of a guard ring structure. Reference is then made to FIG. 9, which illustrates another alternative embodiment where the CMP process removes the metal fill layer 212 at a slower rate. As a result, FIG. 9 illustrates a protrusive through via 2120P. As its name suggests, the protrusive through via 2120P includes a top protrusion or a convex top surface that is higher than the first dielectric layer 206. As will be described below, the top protrusion may affect a cross-sectional profile of a guard ring structure.

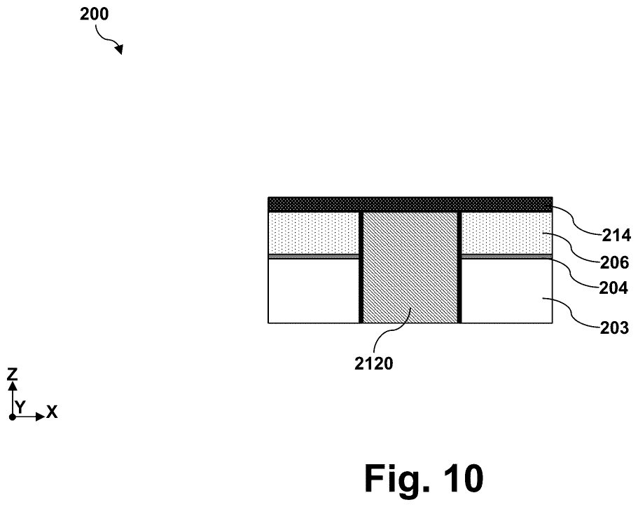

Referring to FIGS. 1 and 10, method 100 includes a block 110 where a protective layer 214 is deposited over the first dielectric layer 206 and the through via 2120. As illustrated in FIG. 10, at block 110, the protective layer 214 is deposited on top surfaces of the through via 2120 (or the recessed through via 2120 shown in FIG. 8 or the protrusive through via 2020P shown in FIG. 9) and the first dielectric layer 206. The protective layer 214 may include a dielectric material having silicon (Si), oxygen (O), hydrogen (H), nitrogen (N), carbon (C), aluminum (Al), or a combination thereof. In some embodiments, the protective layer 214 may include silicon carbonitride, aluminum oxide, or aluminum nitride. The protective layer 214 may be deposited using PECVD or CVD. Because the protective layer 214 is going to withstand etching in a subsequent etching process, a thickness of the protective layer 214 is greater than the thickness of the first ESL 204. A ratio of the thickness of the protective layer 214 to the thickness of the first ESL 204 may be between about 1.1 and about 10. This ratio is not trivial. When the ratio is smaller than 1.1, the protective layer 214 after the patterning process may not be mechanically strong enough to cap the through via 2120. When the ratio is greater than 10, the protective layer 214 may be too thick to interfere formation of metal contact features in the metallization layer immediately over the through via 2120. In some instances, the protective layer 214 may have a thickness between about 100 Å and about 500 Å.

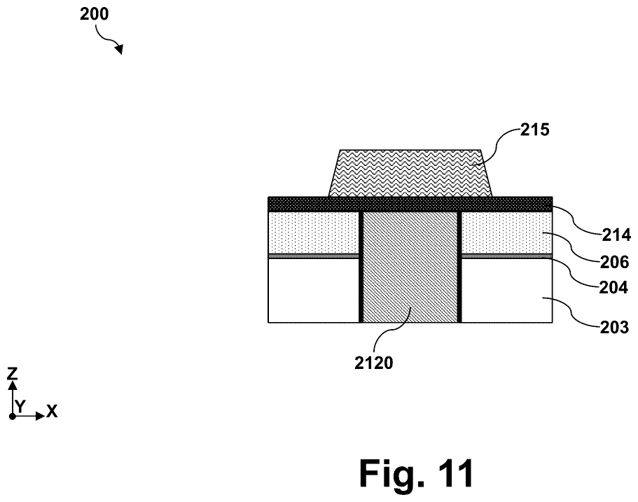

Referring to FIGS. 1 and 11, method 100 includes a block 112 where a patterned mask 215 is formed over the protective layer 214. To form the patterned mask 215, a photoresist layer is deposited over the protective layer 214 using spin-on coating. The deposited photoresist layer may undergo a pre-exposure baking process, exposure to radiation reflected from or transmitted through a photomask, a post-exposure baking process, and developing process, so as to form the patterned mask 215. As shown in FIG. 11, the patterned mask 215 is going to serve as an etch mask to pattern the first dielectric layer 206 and the protective layer 214, the shape and dimensions of the patterned mask 215 determine the shapes and dimensions of a profile of the to-be-formed guard ring structure 2140. As will be described below, the patterned mask 215 may have a circular shape, an oval shape, a racetrack shape, a rectangular shape, a square shape, or even a triangular shape in a top view. In all embodiments, a vertical projection area of the patterned mask 215 completely encloses a vertical projection area of the through via 2120.

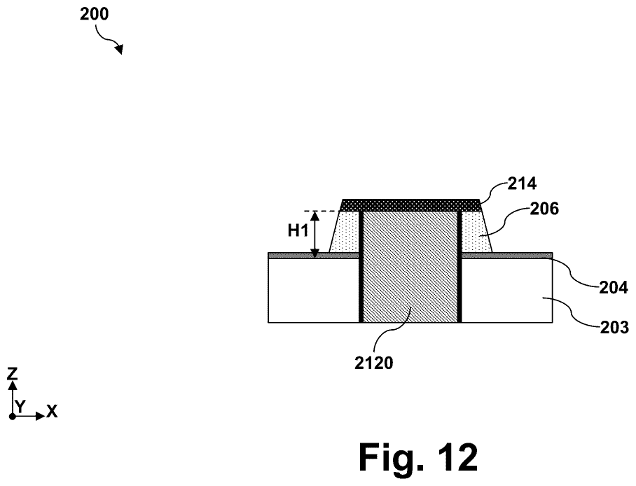

Referring to FIGS. 1 and 12, method 100 includes a block 114 where the protective layer 214 and the first dielectric layer 206 are etched. The patterned mask 215 is then applied as an etch mask to etch the protective layer 214 and the first dielectric layer 206. The etching of the protective layer 214 and the first dielectric layer 206 may include a dry etch process, a wet etch process, or a combination thereof. In some instances, different etch processes or different etchant chemistries may be used to etch the protective layer 214 and the first dielectric layer 206. After the protective layer 214 and the first dielectric layer 206 are patterned, the residual patterned mask 215 may be removed by ashing, stripping, or selective etching. As shown in FIG. 12, the through via 2120 includes a top portion that rises above the top surface of the lower interconnect structure 203 by a first height H1. The patterned first dielectric layer 206 surrounds sidewalls of the top portion of the through via 2120. The patterned protective layer 214 covers the first dielectric layer 206 and the top surface of the through via 2120. In some implementations, the patterned protective layer 214 and the patterned first dielectric layer 206 include tapered sidewalls that taper upward. In some instances, the first height H1 is between about 10 Å and about 500 Å.

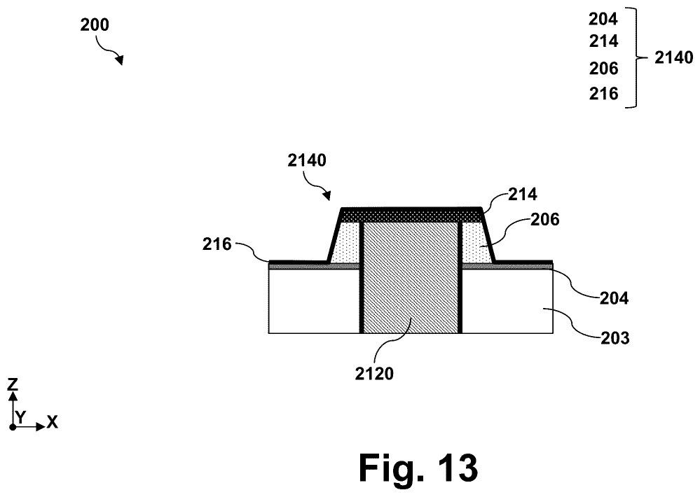

Referring to FIGS. 1 and 13, method 100 includes a block 116 where a third ESL 216 is deposited over the patterned first dielectric layer 206, the patterned protective layer 214, and the first ESL 204. As illustrated in FIG. 13, at block 116, the third ESL 216 is conformally deposited on top surfaces of the protective layer 214 and the first ESL 204 as well as sidewalls of the first dielectric layer 206 and the protective layer 214. The third ESL 216 may include a dielectric material having silicon (Si), oxygen (O), hydrogen (H), nitrogen (N), carbon (C), aluminum (Al), or a combination thereof. In some embodiments, the third ESL 216 may include silicon carbonitride, aluminum oxide, or aluminum nitride. The third ESL 216 may be deposited using PECVD or CVD. In some instances, the third ESL 216 may have a thickness between about 50 Å and about 200 Å. Upon conclusion of the operations at block 116, a guard ring structure 2140 is substantially formed. The guard ring structure 2140 includes the first ESL 204, the first dielectric layer 206, the protective layer 214, and the third ESL 216.

Referring to FIGS. 1 and 14-16, method 100 includes a block 118 where a third dielectric layer 218 is deposited over the third ESL 216. The third dielectric layer 218 may share the same composition with the IMD layers in the lower interconnect structure 203. In some embodiments, the third dielectric layer 218 may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. Example low-k dielectric materials include carbon doped silicon oxide, Xerogel, Aerogel, amorphous fluorinated carbon, benzocyclobutene (BCB), or polyimide.

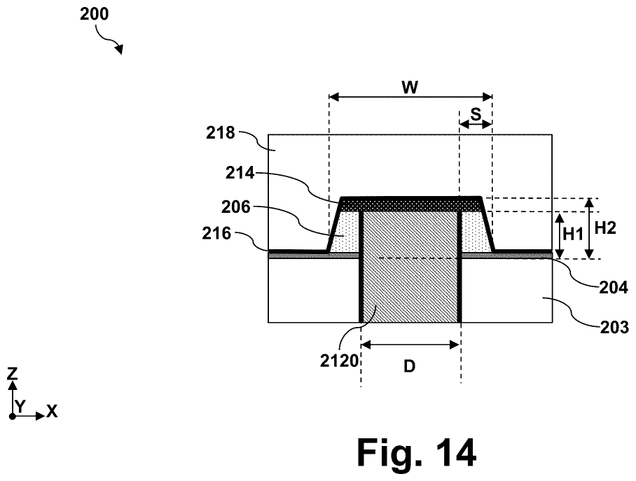

FIG. 14 illustrates an embodiment where the planarization at block 108 removes the metal fill layer 212 and the surrounding dielectric material at substantially the same rate. As a result, top surfaces of the through via 2120 and the first dielectric layer 206 in the guard ring structure 2140 are substantially coplanar. The protective layer 214 in the guard ring structure 2140 serves as a cap over the top surface of the through via 2120. In this embodiment, the top portion of the through via 2120 rises above the first ESL 204 by the first height H1, which is between about 10 Å and about 500 Å. The guard ring structure 2140, which includes the first ESL 204, the first dielectric layer 206, the protective layer 214, and the third ESL 216, rises above the top surface of the lower interconnect structure 203 by a second height H2, which is between about 110 Å and about 1000 Å. The through via 2120 is substantially circular when viewed along the vertical direction (i.e., Z direction) and has a diameter D, which is between about 2 μm and about 12 μm. While sidewalls of the guard ring structure 2140 may be tapered, the widest portion or the width at the base of the guard ring structure 2140 has a width W, which is between about 2.2 μm and about 13 μm. Measured from sidewalls of the through via 2120, the guard ring structure 2140 has a sidewall thickness S, which may be between about 10 nm and about 1000 nm. A ratio of the sidewall thickness S to the diameter D may be between about 0.01 and about 0.5. This ratio is not trivial. When the ratio is smaller than 0.01, the guard ring structure 2140 may not have sufficient thickness to reduce stress exerted on or by the through via 2120. When the ratio is greater than 0.5, the guard ring structure 2140 may take too much real estate while the marginal benefit is limited.

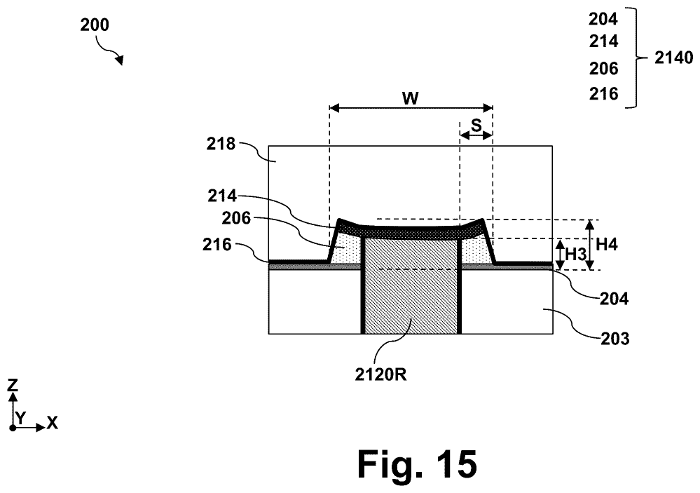

FIG. 15 illustrates an embodiment where the planarization at block 108 removes the metal fill layer 212 at a faster rate. As a result, the recessed top surface of the recessed through via 2120 is lower than the first dielectric layer 206 in the guard ring structure 2140. The protective layer 214 in the guard ring structure 2140 over the top surface of the recessed through via 2120R also includes a recessed profile. In this embodiment, the top portion of the recessed through via 2120R rises above the top surface of the lower interconnect structure 203 by a third height H3, which is smaller than the thickness of the first dielectric layer 206. The guard ring structure 2140, which includes the first ESL 204, the first dielectric layer 206, the protective layer 214, and the third ESL 216, rises above the top surface of the lower interconnect structure 203 by a fourth height H4, which is between about 110 Å and about 1000 Å. The recessed through via 2120R is substantially circular when viewed along the vertical direction (i.e., Z direction) and has a diameter D, which is between about 2 μm and about 12 μm. While sidewalls of the guard ring structure 2140 may be tapered, the widest portion or the width at the base of the guard ring structure 2140 has a width W, which is between about 2.2 μm and about 13 μm. Measured from sidewalls of the through via 2120, the guard ring structure 2140 has a sidewall thickness S, which may be between about 10 nm and about 1000 nm. A ratio of the sidewall thickness S to the diameter D may be between about 0.01 and about 0.5. This ratio is not trivial. When the ratio is smaller than 0.01, the guard ring structure 2140 may not have sufficient thickness to reduce stress exerted on or by the recessed through via 2120R. When the ratio is greater than 0.5, the guard ring structure 2140 may take too much real estate while the marginal benefit is limited.

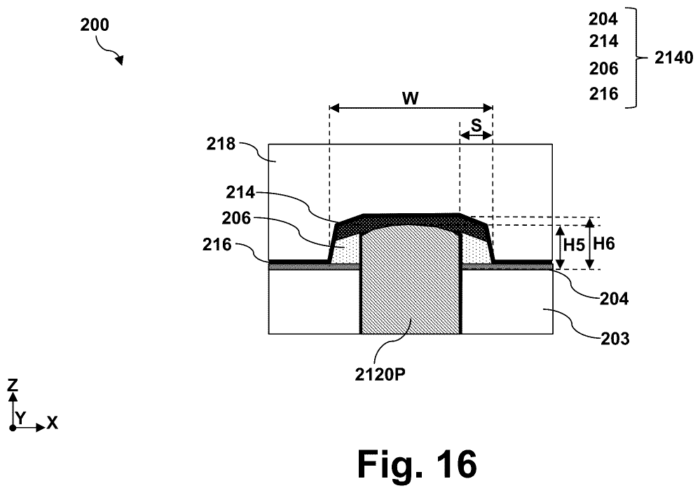

FIG. 16 illustrates an embodiment where the planarization at block 108 removes the dielectric material around the metal fill layer 212 at a faster rate. As a result, the convex top surface of the protrusive through via 2120P is higher than the first dielectric layer 206 in the guard ring structure 2140. The protective layer 214 in the guard ring structure 2140 over the top surface of the protrusive through via 2120P also includes a convex profile. In this embodiment, the top portion of the protrusive through via 2120P rises above the top surface of the lower interconnect structure 203 by a fifth height H5, which is greater than the thickness of the first dielectric layer 206. The guard ring structure 2140, which includes the first ESL 204, the first dielectric layer 206, the protective layer 214, and the third ESL 216, rises above the first ESL 204 by a sixth height H6, which is greater than the second height H2 or the fourth height H4. The protrusive through via 2120P is substantially circular when viewed along the vertical direction (i.e., Z direction) and has a diameter D, which is between about 2 μm and about 12 μm. While sidewalls of the guard ring structure 2140 may be tapered, the widest portion or the width at the base of the guard ring structure 2140 has a width W, which is between about 2.2 μm and about 13 μm. Measured from sidewalls of the through via 2120, the guard ring structure 2140 has a sidewall thickness S, which may be between about 10 nm and about 1000 nm. A ratio of the sidewall thickness S to the diameter D may be between about 0.01 and about 0.5. This ratio is not trivial. When the ratio is smaller than 0.01, the guard ring structure 2140 may not have sufficient thickness to reduce stress exerted on or by the protrusive through via 2120P. When the ratio is greater than 0.5, the guard ring structure 2140 may take too much real estate while the marginal benefit is limited.

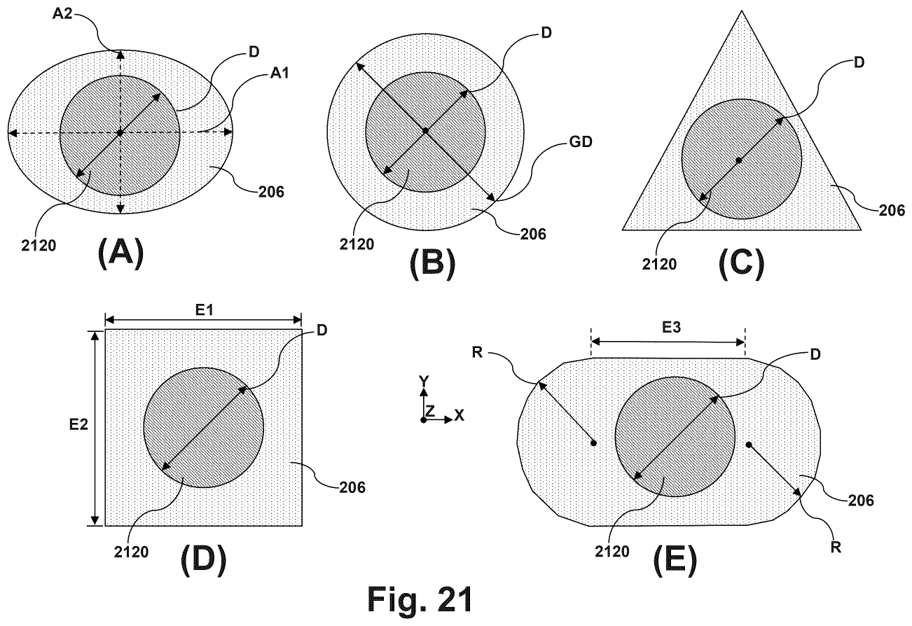

Reference is briefly made to FIG. 21, which illustrates different top-view profiles of the guard ring structure 2140 that vertically overlaps the through via 2120. Profile (A) in FIG. 21 includes an oval-shaped guard ring structure 2140 (shown as the profile of the first dielectric layer 206 as it represents the largest profile of the guard ring structure) that encloses and overlaps the through via 2120, which is circular in shape and has a diameter D. The oval-shaped guard ring structure 2140 includes a long axis A1 and a short axis A2. In order to ensure full enclosure of the through via 2120 by the guard ring structure 2140, the short axis A2 is greater than the diameter D by a margin between 2% and 100%. Profile (B) in FIG. 21 includes a circular guard ring structure 2140 (shown as the profile of the first dielectric layer 206 as it represents the largest profile of the guard ring structure) that encloses and overlaps the through via 2120, which is circular in shape and has a diameter D. The circular guard ring structure 2140 includes a guard ring diameter GD. In order to ensure full enclosure of the through via 2120 by the guard ring structure 2140, the guard ring diameter GD is greater than the diameter D by a margin between 2% and 100%. Profile (C) in FIG. 21 includes a triangular guard ring structure 2140 (shown as the profile of the first dielectric layer 206 as it represents the largest profile of the guard ring structure) that encloses and overlaps the through via 2120, which is circular in shape and has a diameter D. In order to ensure full enclosure of the through via 2120 by the guard ring structure 2140, the shortest distance between a side of the triangular guard ring is between about 10 nm and about 1000 nm. Profile (D) in FIG. 21 includes a rectangular guard ring structure 2140 (shown as the profile of the first dielectric layer 206 as it represents the largest profile of the guard ring structure) that encloses and overlaps the through via 2120, which is circular in shape and has a diameter D. The rectangular guard ring structure 2140 includes a first edge dimension E1 and a second edge dimension E2. In order to ensure full enclosure of the through via 2120 by the guard ring structure 2140, the shorter of E1 and E2 is greater than the diameter D by a margin between 2% and 100%. When E1 is identical to E2, the guard ring structure 2140 has a square top-view profile. Profile (E) in FIG. 21 includes a racetrack-shaped guard ring structure 2140 (shown as the profile of the first dielectric layer 206 as it represents the largest profile of the guard ring structure) that encloses and overlaps the through via 2120, which is circular in shape and has a diameter D. The racetrack-shaped guard ring structure 2140 includes a middle rectangular sandwiched between two semi-circles. The middle rectangle has a non-zero width E3 and a height that equals 2 times of the radius R of the two semi-circles. In order to ensure full enclosure of the through via 2120 by the guard ring structure 2140, the width E3 is not zero and 2 times of the radius R is greater than the diameter D by a margin between 2% and 100%.

When the stress exerted by or on the through via 2120 is homogeneous along all directions, profiles (B) or the square type of profile (D) may be adopted as they distribute stress substantially evenly along all directions. When the stress exerted by or on the through via 2120 is stronger along one direction than the rest directions, profile (A), the rectangular type of profile D, or profile (E) may be adopted such that the long axis or the direction with greater dimensions is aligned with the direction of the stress to better withstand or distribute them. Profile (C) is adopted when the design or geometry of surrounding structures only allows a triangular guard ring structure 2140.

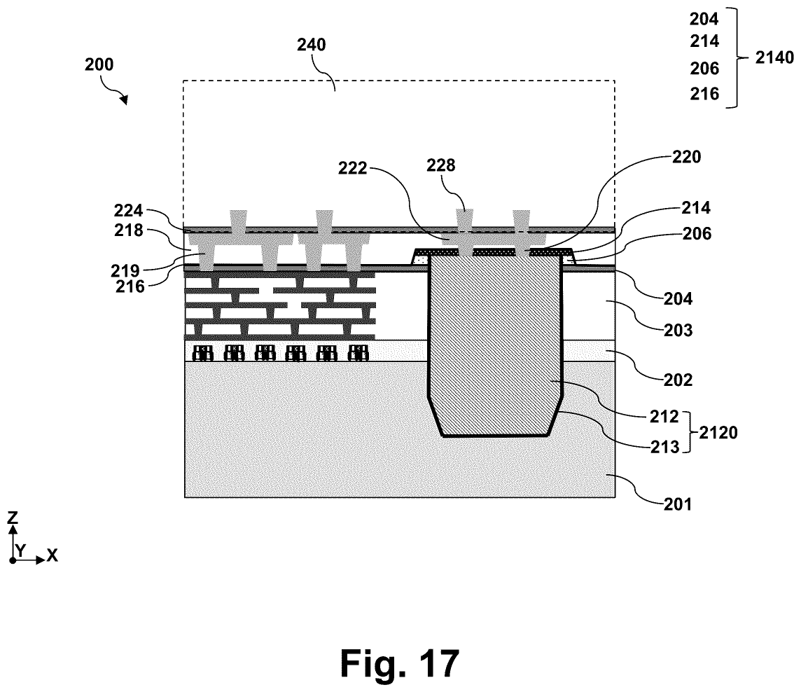

Referring to FIGS. 1 and 17-20, method 100 includes a block 120 where conductive features are formed to couple to a top surface of the through via 2120. The conductive features may come in different configurations, some of which are illustrated in FIGS. 17-20 as examples. Reference is first made to FIG. 17. The metallization layers in the lower interconnect structure 203 and the through via 2120 are coupled upward to an upper interconnect structure 240. The upper interconnect structure 240 may include between two (2) and seventeen (17) levels of metallization layers. After the deposition of the third ESL 216 and the third dielectric layer 218, first vias 220 are formed to extend through the third dielectric layer 218, the third ESL 216 and the protective layer 214 to interface and couple to the through via. A metal line 222 (or a metal island 222) is formed over the first vias 220. The metal line 222 and first vias 220 may include a barrier layer and a metal fill layer, with the barrier layer to space the metal layer apart from the surrounded dielectric layers. The barrier layer may include titanium nitride (TiN) and the metal fill layer may include copper (Cu). In general, the first vias 220 have a smaller height than the second vias 219 outside the via formation region because the top portion of the through via 2120 rises above the first ESL 204. After a planarization step to remove excess materials, a fourth ESL 224 is deposited over the metal line 222. After further dielectric layer are formed over the fourth ESL 224, third vias 228 are formed. The third vias 228 extend through the fourth ESL 224 to couple to the metal line 222. Because the first vias 220 and the third vias 228 have dimensions measured by nanometers while the through via 2120 has a diameter measured by microns, they come in arrays to interface the through via 2120. The array for the first vias 220 may include more vias than the array for the third vias 228 to provide mechanical strength and reduce resistance. In some embodiments, the array for the first vias 220 may include 10 to 90 vias and the array for the third vias 228 may include 2 to 50 vias.

In the configuration illustrated in FIG. 18, the metal line 222 is omitted and fourth vias 2200 with a height greater than that of the first vias 220 may be formed to interface the through via 2120. The fourth vias 2200 also form an array. Unlike the configuration shown in FIG. 17, the number of the fourth vias 2200 and the number of the third vias 228 are the same because each of the third vias 228 is formed over one of the fourth vias 2200.

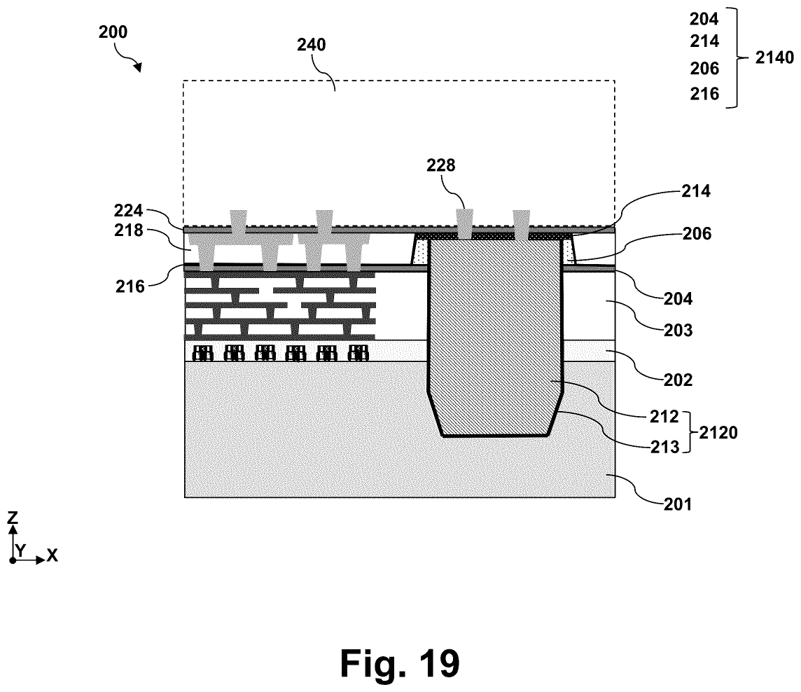

In the configuration illustrated in FIG. 19, the third ESL 216 on the top surface of the protective layer 214 is removed in a planarization process after deposition of the third dielectric layer 218. The fourth ESL 224 is deposited directly on the protective layer 214. It is noted that the third ESL 216 is still present along sidewalls of the first dielectric layer 206. The third vias 228 extend through the fourth ESL 224 and the protective layer 214 to electrically and physically coupled to the through via 2120. Because a bottom surface of the fourth ESL 224 directly interfaces the protective layer 214, it can be said that no third dielectric layer 218 is present between the fourth ESL 224 and the protective layer 214 along the Z direction.

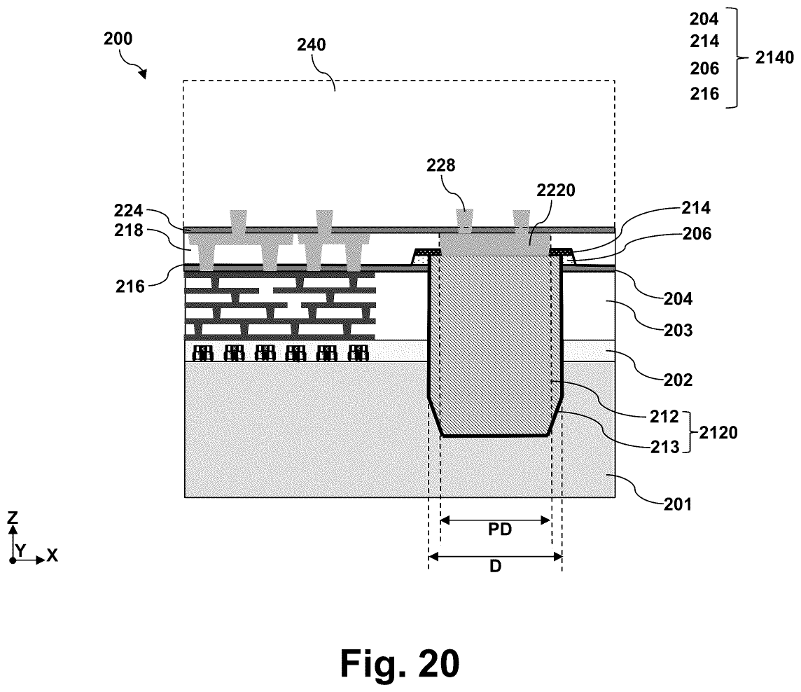

In the configuration illustrated in FIG. 20, the first vias 220 are omitted and a metal pad 2220 is formed to extend through the third dielectric layer 218, the third ESL 216, and the protective layer 214 to couple to the top surface of the through via 2120. The metal pad 2220 may substantially overlap a vertical projection area of the through via 2120. In some embodiments, the metal pad 2220 may be circular in a top view and have a pad diameter PD. A ratio of the pad diameter PD to the diameter D of the through via 2120 may be between 0.9 and about 1.1. That is, a difference between the pad diameter PD and the diameter D of the through via 2120 is equal to or less than 10% of the diameter D. The third vias 228 extends through the fourth ESL 224 to couple to the metal pad 2220.

In subsequent processing, the substrate 201 may be subject to a grinding process, a CMP process, or a combination thereof until the through via 2120 is exposed. The exposed through via 2120 may be used to electrically couple to further structures, such an integrated circuit (IC) die, an interposer, or a package substrate.

In one exemplary aspect, the present disclosure is directed to a method. The method includes receiving a work-in-progress (WIP) structure that includes a substrate, a device layer over the substrate, a plurality of interconnect layers over the device layer and including a via formation region, depositing a first etch stop layer (ESL) over the plurality of interconnect layers, depositing a first dielectric layer over the first ESL, depositing a second ESL over the first dielectric layer, depositing a second dielectric layer over the second ESL, forming a via opening through the second dielectric layer, the second ESL, the first dielectric layer, the first ESL, the via formation region, the device layer, and a depth of the substrate, depositing a metal fill layer over the second dielectric layer and the via opening, planarizing the metal fill layer to form a via structure and expose the first dielectric layer, depositing a protective layer over the via structure and the exposed first dielectric layer, patterning the protective layer and the first dielectric layer to form a guard structure surrounding a portion of the via structure that rises above the first ESL, and depositing a third dielectric layer over the guard structure and the first ESL.

In some embodiments, the method further includes before the depositing of the third dielectric layer, depositing a third ESL over the guard structure and the first ESL. In some embodiments, the depositing of the third ESL includes conformally depositing the third ESL over a top surface of the first ESL, sidewalls of the first dielectric layer, sidewalls of the protective layer, and a top surface of the protective layer. In some embodiments, the first ESL includes silicon carbonitride, aluminum nitride, or aluminum oxide. In some implementations, the first dielectric layer includes silicon oxide. In some embodiments, the protective layer includes silicon carbonitride, aluminum nitride, or aluminum oxide. In some embodiments, a first thickness of the first ESL is smaller than a second thickness of the protective layer. In some instances, a ratio of the second thickness to the first thickness is between about 1.1 and about 10. In some embodiments, the first dielectric layer includes a thickness between about 10 Å and about 500 Å. In some instances, the via formation region includes a plurality of intermetal dielectric layers and is free of conductive features.

In another exemplary aspect, the present disclosure is directed to a contact structure. The contact structure includes a device layer over a substrate, a dielectric structure over the device layer, a first etch stop layer (ESL) over the dielectric structure, a through via extending through the dielectric structure and the device layer, wherein a top portion of the through via rises above the first ESL, a guard ring structure over the first ESL and surrounding the top portion of the through via, a protective layer disposed over the guard ring structure, a second ESL disposed conformally over a top surface of the first ESL, sidewalls of the guard ring structure, sidewalls of the protective layer, and a top surface of the protective layer, and a dielectric layer of the second ESL.

In some embodiments, the through via is substantially circuit in a top view and includes a diameter. In some implementations, the guard ring structure includes a thickness measured from a sidewall of the through via and a ratio of the thickness to the diameter is between about 0.01 and about 0.5. In some embodiments, in a top view, the guard ring structure includes a circular shape, a rectangular shape, an oval shape, or a racetrack shape. In some embodiments, a first thickness of the first ESL is smaller than a second thickness of the protective layer. In some embodiments, a ratio of the second thickness to the first thickness is between about 1.1 and about 10.

In yet another exemplary aspect, the present disclosure is directed to a contact structure. The contact structure includes a device layer over a substrate, a dielectric structure over the device layer, a first etch stop layer (ESL) over the dielectric structure, a through via extending through the dielectric structure and the device layer, wherein a top portion of the through via extends through the first ESL, a guard ring structure over the first ESL and surrounding the top portion of the through via, a protective layer disposed over the guard ring structure, a second ESL disposed conformally over the top surface of the first ESL, sidewalls of the guard ring structure, sidewalls of the protective layer, and a top surface of the protective layer, and a dielectric layer of the second ESL. The top portion includes a height measured from a top surface of the dielectric structure. The height is between about 5 Å and about 15 Å. The through via is substantially circuit in a top view and includes a diameter between about 2 μm and about 12 μm.

In some embodiments, the first ESL, the protective layer and the second ESL include silicon carbonitride, aluminum nitride, or aluminum oxide. In some embodiments, the guard ring structure includes silicon oxide. In some implementations, the contact structure further includes a metal line extending through the dielectric layer, the second ESL, and the protective layer to interface a top surface of the through via. In some embodiments, the metal line includes a width and a ratio of the diameter of the through via and the width of the metal line is between about 0.9 and about 1.1.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a work-in-progress (WIP) structure that includes:
a substrate,
a device layer over the substrate, and
a plurality of interconnect layers over the device layer and comprising a via formation region;
depositing a first etch stop layer (ESL) over the plurality of interconnect layers;
depositing a first dielectric layer over the first ESL;
depositing a second ESL over the first dielectric layer;
depositing a second dielectric layer over the second ESL;
forming a via opening through the second dielectric layer, the second ESL, the first dielectric layer, the first ESL, the via formation region, the device layer, and a depth of the substrate;
depositing a metal fill layer over the second dielectric layer and the via opening;
planarizing the metal fill layer to form a via structure and expose the first dielectric layer;
depositing a protective layer over the via structure and the exposed first dielectric layer;
patterning the protective layer and the first dielectric layer to form a guard structure surrounding a portion of the via structure that rises above the first ESL; and
depositing a third dielectric layer over the guard structure and the first ESL.

2. The method of claim 1, further comprising:
before the depositing of the third dielectric layer, depositing a third ESL over the guard structure and the first ESL.

3. The method of claim 2, the depositing of the third ESL comprises conformally depositing the third ESL over a top surface of the first ESL, sidewalls of the first dielectric layer, sidewalls of the protective layer, and a top surface of the protective layer.

4. The method of claim 1, wherein the first ESL comprises silicon carbonitride, aluminum nitride, or aluminum oxide.

5. The method of claim 1, wherein the first dielectric layer comprises silicon oxide.

6. The method of claim 1, wherein the protective layer comprises silicon carbonitride, aluminum nitride, or aluminum oxide.

7. The method of claim 1, wherein a first thickness of the first ESL is smaller than a second thickness of the protective layer.

8. The method of claim 7, wherein a ratio of the second thickness to the first thickness is between about 1.1 and about 10.

9. The method of claim 1, wherein the first dielectric layer comprises a thickness between about 10 Å and about 500 Å.

10. The method of claim 1, wherein the via formation region comprises a plurality of intermetal dielectric layers and is free of conductive features.

11. A contact structure, comprising:
a device layer over a substrate;
a dielectric structure over the device layer;
a first etch stop layer (ESL) over the dielectric structure;
a through via extending through the dielectric structure and the device layer, wherein a top portion of the through via rises above the first ESL;
a guard ring structure over the first ESL and surrounding the top portion of the through via;
a protective layer disposed over the guard ring structure;
a second ESL disposed conformally over a top surface of the first ESL, sidewalls of the guard ring structure, sidewalls of the protective layer, and a top surface of the protective layer; and
a dielectric layer of the second ESL.

12. The contact structure of claim 11,
wherein the through via is substantially circuit in a top view and comprises a diameter,
wherein the guard ring structure comprises a thickness measured from a sidewall of the through via,
wherein a ratio of the thickness to the diameter is between about 0.01 and about 0.5.

13. The contact structure of claim 12, wherein, in a top view, the guard ring structure comprises a circular shape, a rectangular shape, an oval shape, or a racetrack shape.

14. The contact structure of claim 11, wherein a first thickness of the first ESL is smaller than a second thickness of the protective layer.

15. The contact structure of claim 14, wherein a ratio of the second thickness to the first thickness is between about 1.1 and about 10.

16. A contact structure, comprising:
a device layer over a substrate;
a dielectric structure over the device layer;
a first etch stop layer (ESL) over the dielectric structure;
a through via extending through the dielectric structure and the device layer, wherein a top portion of the through via extends through the first ESL;
a guard ring structure over the first ESL and surrounding the top portion of the through via;
a protective layer disposed over the guard ring structure;
a second ESL disposed conformally over the top surface of the first ESL, sidewalls of the guard ring structure, sidewalls of the protective layer, and a top surface of the protective layer; and
a dielectric layer of the second ESL,
wherein the top portion comprises a height measured from a top surface of the dielectric structure,
wherein the height is between about 5 Å and about 15 Å,
wherein the through via is substantially circuit in a top view and comprises a diameter between about 2 μm and about 12 μm.

17. The contact structure of claim 16, wherein the first ESL, the protective layer and the second ESL comprise silicon carbonitride, aluminum nitride, or aluminum oxide.

18. The contact structure of claim 16, wherein the guard ring structure comprises silicon oxide.

19. The contact structure of claim 16, further comprising:
a metal line extending through the dielectric layer, the second ESL, and the protective layer to interface a top surface of the through via.

20. The contact structure of claim 19,
wherein the metal line comprises a width,
wherein a ratio of the diameter of the through via and the width of the metal line is between about 0.9 and about 1.1.
